(19) United States
(12) Patent Application Publication
(10) Pub. No.: US 2024/0113178 A1
(43) Pub. Date: Apr. 4, 2024

(54) VTFETS WITH WRAP-AROUND BACKSIDE CONTACTS

(71) Applicant: INTERNATIONAL BUSINESS MACHINES CORPORATION, Armonk, NY (US)

(72) Inventors: Brent A. Anderson, Jericho, VT (US); Ruilong Xie, Niskayuna, NY (US); Nicholas Anthony Lanzillo, Wynantskill, NY (US); Albert M. Chu, Nashua, NH (US); Lawrence A. Clevenger, Saratoga Springs, NY (US); REINALDO VEGA, Mahopac, NY (US)

(21) Appl. No.: 17/957,599

(22) Filed: Sep. 30, 2022

(51) Int. Cl. H01L 29/417; H01L 21/285; H01L 29/40; H01L 29/45; H01L 29/66; H01L 29/78

(52) U.S. Cl. CPC H01L 29/41741; H01L 21/28518; H01L 29/401; H01L 29/45; H01L 29/66666; H01L 29/7827

(57) ABSTRACT

Semiconductor device and methods of forming the same include a semiconductor channel. A top source/drain structure is on the semiconductor channel. A bottom source/drain structure is under the semiconductor channel. The bottom source/drain structure includes a doped semiconductor part and a conductor part, with the conductor part covering a bottom surface of the doped semiconductor part.

### BACKGROUND

The present invention generally relates to semiconductor devices and, more particularly, to the fabrication of vertical transfer field effect transistors (VTFETs) having wrap-around backside contacts.

A VTFET is a type of transistor where the source and drain of the device are vertically stacked, with a channel structure between them. Using VTFETs can increase the areal device density of an integrated circuit over planar FETs.

### SUMMARY

A semiconductor device includes a semiconductor channel. A top source/drain structure is on the semiconductor channel. A bottom source/drain structure is under the semiconductor channel. The bottom source/drain structure includes a doped semiconductor part and a conductor part, with the conductor part covering a bottom surface of the doped semiconductor part.

A semiconductor includes a first semiconductor channel and a second semiconductor channel. A first top source/drain structure is on the first semiconductor channel. A second top source/drain structure is on the second semiconductor channel. A shared bottom source/drain structure is under the first semiconductor channel and the second semiconductor channel. The shared bottom source/drain structure includes a doped semiconductor part and a conductor part, with the conductor part covering a bottom surface of the doped semiconductor part.

A method of forming a semiconductor device includes forming a first semiconductor fin on a substrate. A bottom source/drain structure is formed under the first semiconductor fin. A top source/drain structure is formed over the first semiconductor fin. The substrate is removed and a bottom surface of the bottom source/drain structure is metallized.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of a vertical transport field effect transistor (VTFET) having a metallized bottom source/drain structure, showing the masking of channel regions on a substrate in accordance with an embodiment of the present invention;

FIG. 2 is a cross-sectional view of a step in the fabrication of a VTFET having a metallized bottom source/drain structure, showing an etch to form channel fins in a semiconductor substrate in accordance with an embodiment of the present invention;

FIG. 3 is a cross-sectional view of a step in the fabrication of a VTFET having a metallized bottom source/drain structure, showing the formation of a bottom source/drain structure at the base of the channel fins in accordance with an embodiment of the present invention;

FIG. 4 is a cross-sectional view of a step in the fabrication of a VTFET having a metallized bottom source/drain structure, showing the formation of a bottom spacer on the bottom source/drain structure accordance with an embodiment of the present invention;

FIG. 5 is a cross-sectional view of a step in the fabrication of a VTFET having a metallized bottom source/drain structure, showing the formation of a gate stack and top spacer over the bottom spacer in accordance with an embodiment of the present invention;

FIG. 6 is a cross-sectional view of a step in the fabrication of a VTFET having a metallized bottom source/drain structure, showing the formation of top source/drain structures on the semiconductor fins in accordance with an embodiment of the present invention;

FIG. 7 is a cross-sectional view of a step in the fabrication of a VTFET having a metallized bottom source/drain structure, showing the formation of a top contact to the top source/drain structures in accordance with an embodiment of the present invention;

FIG. 8 is a cross-sectional view of a step in the fabrication of a VTFET having a metallized bottom source/drain structure, showing the removal of the substrate from the bottom source/drain structure in accordance with an embodiment of the present invention;

FIG. 9 is a cross-sectional view of a step in the fabrication of a VTFET having a metallized bottom source/drain structure, showing the formation of a recess in the exposed surface of the bottom source/drain structure in accordance with an embodiment of the present invention;

FIG. 10 is a cross-sectional view of a step in the fabrication of a VTFET having a metallized bottom source/drain structure, showing the formation of a metallization layer on the bottom source/drain structure in accordance with an embodiment of the present invention;

FIG. 11 is a cross-sectional view of a step in the fabrication of a VTFET having a metallized bottom source/drain structure, showing the formation of an electrical contact to the metallization layer of the bottom source/drain structure in accordance with an embodiment of the present invention;

FIG. 12 is a block/flow diagram of a method of fabricating a VTFET having a metallized bottom source/drain structure, in accordance with an embodiment of the present invention;

FIG. 13 is a cross-sectional view of an embodiment of a VTFET having a metallized bottom source/drain structure, showing a wrap-around metallization layer on the bottom source/drain structure in accordance with an embodiment of the present invention;

FIG. 14 is a cross-sectional view of an embodiment of a VTFET having a metallized bottom source/drain structure, showing a metallization layer on only the bottom surface of the bottom source/drain structure in accordance with an embodiment of the present invention;

FIG. 15 is a cross-sectional view of an embodiment of a VTFET having a metallized bottom source/drain structure, showing a recess in the bottom source/drain structure with a metallization layer filling the recess and wrapping around sidewalls of the bottom source/drain structure in accordance with an embodiment of the present invention; and

FIG. 16 is a cross-sectional view of an embodiment of a VTFET having a metallized bottom source/drain structure, showing a recess in the bottom source/drain structure with a metallization layer filling the recess in accordance with an embodiment of the present invention.

### DETAILED DESCRIPTION

When using backside power distribution networks for devices, such as vertical transport field effect transistors (VTFETs), backside contact resistance may be reduced by replacing part of a bottom source/drain structure with a metal conductor, e.g. by forming a silicide on the surface of the bottom source/drain. This may be performed after the device and back-end-of-line layers have been formed, flipping the chip over to access the underside of the device. Additionally, the surface area of the interface between the metallized layer and the bottom source/drain structure may be increased by forming the metallized layer along sidewalls of the bottom source/drain structure and by recessing the bottom source/drain structure.

Embodiments that use wrap-around backside contacts may include a variety of different device types. For example, multiple VTFETs may be connected in parallel, with a shared backside wrap-around contact that connects the VTFETs to a single line. In another example, multiple VTFETs may have a shared backside wrap-around contact that connects the VTFETs to a single line and a shared frontside contact. In another example, multiple VTFETs may be connected in series, with a shared backside wrap-around contact that is not connected to a separate line. Furthermore, while one particular process is shown for the formation of VTFETs, it should be understood that there is substantial variability in how such FETs may be formed, and those having ordinary skill in the art will be able to design the devices as appropriate for their needs.

In some embodiments, a single integrated circuit may include multiple VTFETs. VTFETs may be connected in serial or in parallel, with a backside wrap-around contact that bridges the source/drain regions of multiple such devices. Other VTFETs in the same circuit may not have metallized bottom source/drain structure. Some VTFETs may have backside contacts that provide electrical connectivity between the metallized bottom source/drain regions of VTFETs and a backside back-end-of-line layer. Some VTFETs may lack backside contacts, where the metallized bottom source/drain region provides electrical communication between devices.

Referring now to FIG. 1, a cross-sectional view of a step in the fabrication of VTFETs with wrap-around backside contacts is shown. A hardmask pattern 104 is formed on a semiconductor substrate 102. The hardmask pattern 104 can be formed from any appropriate hardmask material, such as silicon nitride, and can be patterned by any appropriate process, such as photolithographic patterning. The hardmask pattern 104 establishes locations on the semiconductor substrate 102 where semiconductor fins will be formed.

The semiconductor substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate.

Two distinct device regions are shown, established by the masks 104 on the semiconductor substrate 102. It should be understood that any appropriate number of device regions may be shown, and that the present principles may be applied to a single VTFET in isolation as well as to multiple VTFETs that are connected to one another.

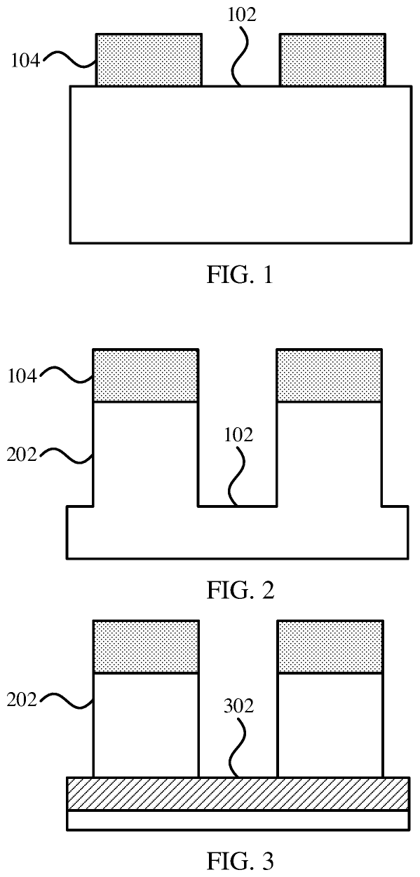

Referring now to FIG. 2, a cross-sectional view of a step in the fabrication of VTFETs with wrap-around backside contacts is shown. The semiconductor substrate 102 is anisotropically etched, for example using reactive ion etching (RIE) around the hardmask pattern 104, thereby forming fins 202. It should be understood that, in some alternative embodiments, the fins 202 can be formed from a material that is distinct from the material of the semiconductor substrate 102, for example by etching down into a separate semiconductor layer (not shown) formed between the hardmask pattern 104 and the semiconductor substrate 102. The height of the fins 202 can be controlled by timing the anisotropic etch to determine the depth of the etch.

RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation. Alternatively, the fins 202 can be formed by spacer imaging transfer.

Referring now to FIG. 3, a cross-sectional view of a step in the fabrication of VTFETs with wrap-around backside contacts is shown. Bottom source/drain regions 302 are formed in the semiconductor substrate 102 by, e.g., doping in situ while bottom source/drain regions 302 are epitaxially grown, followed by an anneal, or by dopant implantation. The dopant may include one or more dopant species of any conductivity type. As used herein, the term “conductivity type” denotes a dopant region being p-type or n-type. The selection of the dopant will depend on the designed properties of the VTFET device. As shown, the dopant will partially infiltrate the material underneath the fins 202. It should be understood the cross-sectional view is shown along the edge of the fins 202, to illustrate the presence of the dopant underneath the fins 202.

As used herein, “p-type” refers to the addition of impurities to an intrinsic semiconductor that creates deficiencies of valence electrons. In a silicon-containing substrate, examples of p-type dopants, i.e., impurities, include but are not limited to: boron, aluminum, gallium and indium. As used herein, “n-type” refers to the addition of impurities that contributes free electrons to an intrinsic semiconductor. In a silicon containing substrate, examples of n-type dopants, i.e., impurities, include but are not limited to antimony, arsenic and phosphorous. The dopants may be implanted into the semiconductor substrate 102 by an ion implantation process, whereby dopant ions are accelerated in an electric field and embed themselves into the semiconductor substrate 102 upon impact.

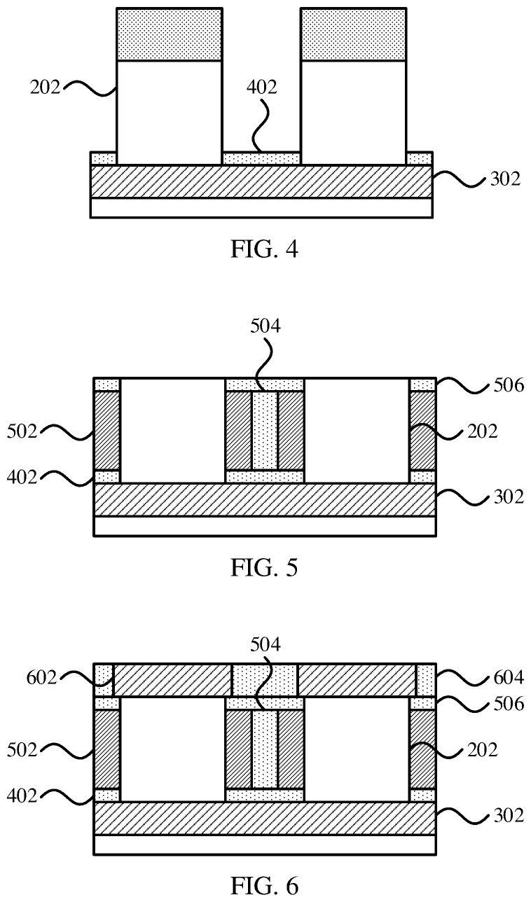

Referring now to FIG. 4, a cross-sectional view of a step in the fabrication of VTFETs with wrap-around backside contacts is shown. A bottom spacer 402 is formed from any appropriate dielectric material. The bottom spacer 402 provides electrical insulation between the bottom source/drain regions 302 and a gate stack. The bottom spacer 402 may be formed by a deposition process, such as physical vapor deposition (PVD) or chemical vapor deposition (CVD), followed by etching to form the spacer at the bottom while removing it from the fin sidewall.

In PVD, a sputtering apparatus may include direct-current diode systems, radio frequency sputtering, magnetron sputtering, or ionized metal plasma sputtering. In embodiments that use GCIB deposition, a high-pressure gas is allowed to expand in a vacuum, subsequently condensing into clusters. The clusters can be ionized and directed onto a surface, providing a highly anisotropic deposition.

In some embodiments, formation of the bottom spacer 402 may include an etch down into the bottom source/drain region 302, with the bottom spacer 402 separating the bottom source/drain region 302 into distinct device regions. In such embodiments, the bottom spacer 402 may include multiple dielectric layers, including a liner layer that is formed on sidewalls of the separated bottom source/drain region 302 of respective device regions. The liner may be formed from a dielectric material that is selectively etchable with respect to the material of the bottom source/drain region 302, such that the liner may be etched back to expose the sidewalls of the separated bottom source/drain regions in a further processing step.

Referring now to FIG. 5, a cross-sectional view of a step in the fabrication of VTFETs with wrap-around backside contacts is shown. Gate stacks 502 are formed on sidewalls of the fins 202 and may include multiple layers, such as a gate dielectric, a work function layer, and a gate conductor. The gate stacks 502 may be recessed below a height of the fins 202 and a top spacer 506 may be formed on top of the gate stacks 502 from any appropriate dielectric material using a self-aligned process.

A dielectric 504 may be filled in between the gate stacks 502 of the devices to provide electrical insulation between adjacent gates. Such a dielectric 504 may be formed by etching through the gate stack 502 between adjacent fins 202, followed by a deposition of dielectric material. In some embodiments, the dielectric 504 may be omitted to leave the adjacent fins 202 connected by a gate stack 502.

The gate stacks 502 may include, for example, a gate dielectric and a gate conductor, which may be formed by any appropriate conformal deposition process, such as chemical vapor deposition (CVD) or atomic layer deposition (ALD). The gate dielectric may be formed from any appropriate dielectric material, such as a high-k dielectric. The gate conductor may be formed from any appropriate conductive material. After conformal deposition of a dielectric or conductor material, a selective anisotropic etch may be used to remove the material from horizontal surfaces.

Examples of high-k dielectric materials include but are not limited to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

Examples of conductive materials may include conductive metals such as, e.g., tungsten, nickel, titanium, molybdenum, tantalum, copper, platinum, silver, gold, ruthenium, iridium, rhenium, rhodium, cobalt, and alloys thereof. The gate conductor may alternatively be formed from a doped semiconductor material such as, e.g., doped polysilicon.

CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In ALD, chemical precursors react with the surface of a material one at a time to deposit a thin film on the surface.

The dielectric fill 504 and the top spacer 506 may be formed from any appropriate dielectric material, by any appropriate deposition process. After the top spacer 506 is deposited, a chemical mechanical planarization (CMP) may be performed to expose the top surfaces of the fins 202. CMP is performed using, e.g., a chemical or granular slurry and mechanical force to gradually remove upper layers of the device. The slurry may be formulated to be unable to dissolve, for example, the work function metal layer material, resulting in the CMP process's inability to proceed any farther than that layer.

Referring now to FIG. 6, a cross-sectional view of a step in the fabrication of VTFETs with wrap-around backside contacts is shown. Top source/drain regions 602 are formed on the top surfaces of the semiconductor fins 202. In some cases the top source/drain regions 602 may be formed by epitaxial growth with in situ doping. An interlayer dielectric 604 is deposited over and around the top source/drain regions 602 and is polished down, for example using a CMP process, to expose the top surfaces of the top source/drain regions 602.

The terms “epitaxial growth” and “epitaxial deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

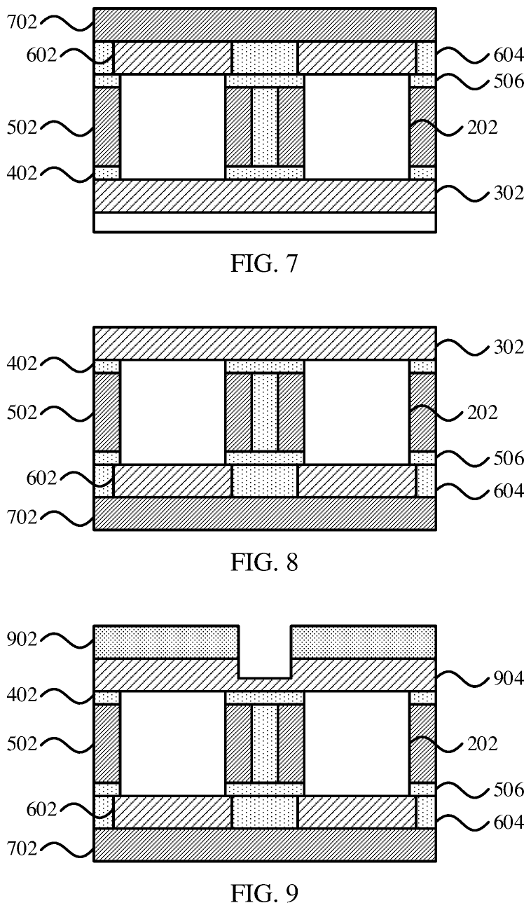

Referring now to FIG. 7, a cross-sectional view of a step in the fabrication of VTFETs with wrap-around backside contacts is shown. A top contact 702 is formed, in this example connecting the top source/drain regions 602 of adjacent devices. The top contact 702 may be formed from any appropriate conductive material and may be deposited and patterned according to any appropriate deposition and lithography process.

Although a single, shared top contact 702 is shown, other embodiments are also contemplated. For example, each device may have a different respective top contact, making electrical contact with the respective top source/drain regions 602 of each device.

Additional layers of metallization may be formed over the top contact, for example to form back-end-of-line (BEOL) layers. The BEOL layers may include conductive lines and vias that provide power and signal communications to devices. For example, each successive BEOL layer may have lines that are perpendicular to lines in the previous BEOL layer, with vias that penetrate to lower layers to provide electrical communication between the BEOL layers and the devices.

Referring now to FIG. 8, a cross-sectional view of a step in the fabrication of VTFETs with wrap-around backside contacts is shown. The wafer may be flipped over and the substrate 102 may be removed, for example using a selective etch or polishing process. The removal of the semiconductor substrate 102 exposes the bottom source/drain region 302.

Referring now to FIG. 9, a cross-sectional view of a step in the fabrication of VTFETs with wrap-around backside contacts is shown. A mask 902 is formed over the bottom source/drain region 302 using any appropriate photolithographic process. An anisotropic etch, such as a timed RIE, may be used to etch back an exposed portion of the bottom source/drain region 302, leaving recessed bottom source/drain region 902.

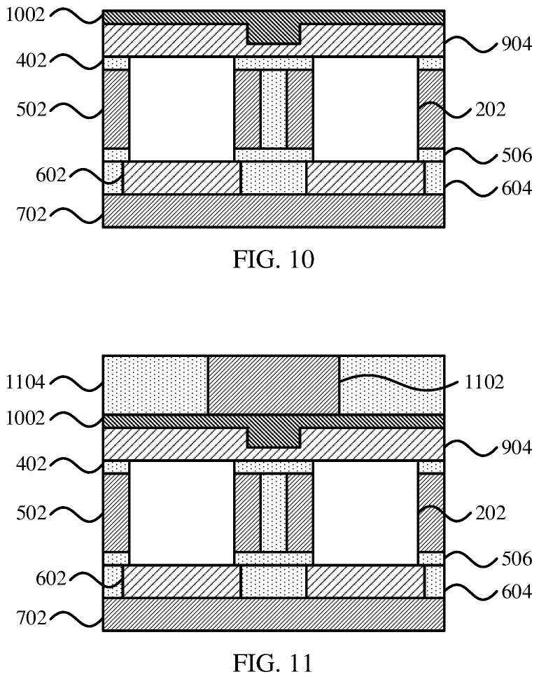

Referring now to FIG. 10, a cross-sectional view of a step in the fabrication of VTFETs with wrap-around backside contacts is shown. The mask 902 is selectively etched away, exposing the recessed bottom source/drain region 904. A layer of conductive material 1002 is deposited over the recessed bottom source/drain region 904, filling the recess. The layer of conductive material 1002 forms a wrap-around contact to the bottom source/drain region 904, thereby reducing the resistance of the structure.

The layer of conductive material 1002 may be formed by, e.g., conformally depositing a layer of metal over the bottom source/drain region 904 and performing an anneal. The anneal causes the metal to diffuse into the semiconductor material of the bottom source/drain region 904. For example, a layer of nickel may be deposited and annealed to form a layer of silicide as the layer of conductive material 1002.

Referring now to FIG. 11, a cross-sectional view of a step in the fabrication of VTFETs with wrap-around backside contacts is shown. A backside contact 1102 may be formed by depositing any appropriate conductive material and patterning the deposited conductor. An interlayer dielectric 1104 may be formed around the backside contact 1102 by, e.g., depositing a dielectric material using any appropriate deposition process and polishing the dielectric material back to expose the backside contact 1102. Any number of backside BEOL layers may be formed over the backside contact, including one or more metallization layers to provide backside power and signal distribution.

A metallization layer and electrical contact may also be formed to the top source/drain regions 602. As such, both the top source/drains 602 and the bottom source/drain 904 may both be metallized to reduce electrical resistance on both sides of the device. The top source/drain structures 602 may similarly include wrap-around metallization and may include a recess to further include surface area of the interface between the semiconductor and metallized portions.

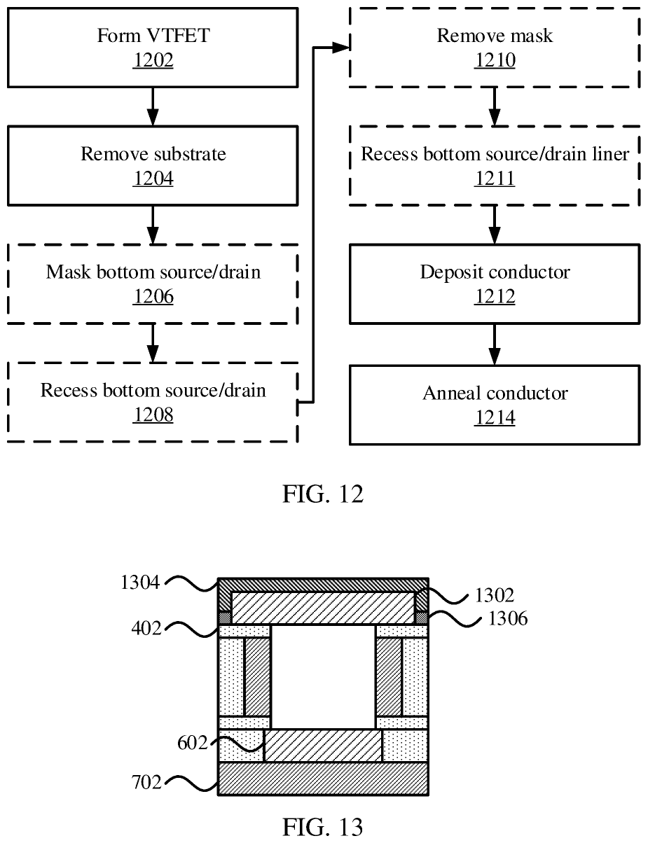

Referring now to FIG. 12, a method of fabricating VTFETs with wrap-around backside contacts is shown. Block 1202 forms one or more VTFETs on a substrate, with a bottom source/drain region being formed between the channels of the VTFETs and the substrate. Block 1204 removes the substrate from the backside of the VTFETs, exposing the bottom source/drain region. The removal of the substrate may be performed using a CMP process or a selective etch.

Blocks 1206-1211 include optional steps that can increase the surface area of the interface between the metallized portion of the bottom source/drain structure and the doped semiconductor portion of the bottom source/drain structure. Block 1206 masks the bottom source/drain, covering portions of the bottom source/drain and leaving at least some of the bottom source/drain exposed. In cases where the bottom source/drain connects to adjacent VTFETs, a portion of the bottom source/drain between the two VTFETs may be left exposed by the pattern mask. Block 1208 then recesses the bottom source/drain using an anisotropic etch to remove material from the exposed portion of the bottom source/drain. Block 1210 etches away the mask using a selective etch. As an alternative to the formation of the recess, or in addition to the same, block 1211 may recess a dielectric liner on sidewalls of the bottom source/drain to expose those sidewalls. Block 1211 may etch the liner down to the bottom spacer or may leave behind a remnant of the dielectric liner.

Block 1212 deposits a conductive material in the recess of the bottom source/drain region and over the non-recessed portions thereof. The conductive material reduces the resistance of the bottom source/drain region and provides a low interface resistance between the conductive material and the bottom source/drain material due to a high surface area.

Referring now to FIG. 13, a cross-sectional view of a VTFET with a backside contact is shown. Whereas the embodiments described above show multiple adjacent VTFETs, this view shows a single VTFET. It should be understood that the present embodiments may include any appropriate number of VTFETs, which may or may not be connected to one another by a shared metallized bottom source/drain structure.

In this view, a metallized layer 1304 is formed on a bottom source/drain 1302. Some embodiments may include a metallized layer 1304 that wraps around the bottom source/drain 1302, for example including conductive material on sidewalls of the bottom source/drain 1302. The wrap-around structure may be formed by, e.g., etching back a dielectric liner on sidewalls of the bottom source/drain 1302, which exposes the sidewalls and leaves room for deposition thereon and which may leave a liner remnant 1306.

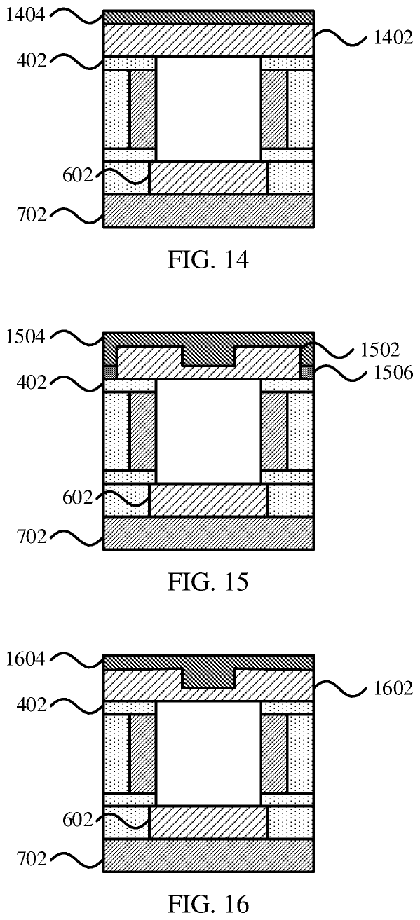

Referring now to FIG. 14, a cross-sectional view of a VTFET with a backside contact is shown. In this view, a metallized layer 1404 is formed on the horizontal surface of a bottom source/drain 1402, without a recess in the middle and without formation on the sidewalls. Such embodiments can be formed without additional etching steps, while still benefitting from an improved resistance of the bottom source/drain 1402.

Referring now to FIG. 15, a cross-sectional view of a VTFET with a backside contact is shown. In this view, the bottom source/drain 1502 includes a recess, and the metallized layer 1504 is formed on the surfaces of the recess as well as the sidewalls of the bottom source/drain 1502. The larger surface are of the interface between the bottom source/drain 1502 and the metallized layer 1504 minimizes the resistance between these two structures. A liner remnant 1506 may remain from the dielectric liner that is etched back to expose the sidewalls of the bottom source/drain 1502.

Referring now to FIG. 16, a cross-sectional view of a VTFET with a backside contact is shown. In this view, the bottom source/drain 1602 includes a recess, with a metallized layer 1604 being formed on the surfaces of the recess and on the horizontal surface of the bottom source/drain 1602. Even without wrapping around the sidewalls of the bottom source/drain 1602, the additional surface area of the recess improves the resistance of the interface between the metallized layer 1064 and the bottom source/drain 1602.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates other vise. It will be further understood that the terms “comprises,” “comprising,” “includes” and/or “ding,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below.” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of VTFETs with wrap-around backside contacts (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a semiconductor channel;
a top source/drain structure on the semiconductor channel; and
a bottom source/drain structure under the semiconductor channel, the bottom source/drain structure including a doped semiconductor part and a conductor part, with the conductor part covering a bottom surface of the doped semiconductor part.

2. The semiconductor device of claim 1, wherein the doped semiconductor part of the bottom source/drain structure includes a recess and wherein the conductor part of the bottom source/drain structure fills the recess.

3. The semiconductor device of claim 1, wherein the conductor part of the bottom source/drain structure covers at least part of outer sidewalls of the doped semiconductor part of the bottom source/drain structure.

4. The semiconductor device of claim 3, further comprising:
a gate stack on sidewalls of the semiconductor channel;
a bottom spacer between the bottom source/drain structure and the gate stack.
a dielectric liner remnant on outer sidewalls of the doped semiconductor part of the bottom source/drain structure, between the conductor part of the bottom source/drain structure and the bottom spacer.

5. The semiconductor device of claim 1, further comprising:
a first electrical contact on a top surface of the top source/drain structure; and
a second electrical contact on a bottom surface of the conductor part of the bottom source/drain structure.

6. The semiconductor device of claim 1, further comprising a gate stack on sidewalls of the semiconductor channel, wherein the bottom source/drain structure extends laterally past the gate stack and the top source/drain structure does not extend laterally past the gate stack.

7. The semiconductor device of claim 1, wherein the top source/drain structure includes a doped semiconductor part and a conductor part.

8. A semiconductor device, comprising:
a first semiconductor channel;
a first top source/drain structure on the first semiconductor channel;
a second semiconductor channel;
a second top source/drain structure on the second semiconductor channel; and
a shared bottom source/drain structure under the first semiconductor channel and the second semiconductor channel, the shared bottom source/drain structure including a doped semiconductor part and a conductor part, with the conductor part covering a bottom surface of the doped semiconductor part.

9. The semiconductor device of claim 8, wherein the doped semiconductor part of the shared bottom source/drain structure includes a recess and wherein the conductor part of the shared bottom source/drain structure fills the recess.

10. The semiconductor device of claim 9, wherein the recess is positioned between the first semiconductor channel and the second semiconductor channel.

11. The semiconductor device of claim 8, wherein the conductor part of the shared bottom source/drain structure covers at least part of outer sidewalls of the doped semiconductor part of the bottom source/drain structure.

12. The semiconductor device of claim 11, further comprising:
a gate stack on sidewalls of the first semiconductor channel;
a bottom spacer between the shared bottom source/drain structure and the gate stack.
a dielectric liner remnant on outer sidewalls of the doped semiconductor part of the bottom source/drain structure, between the conductor part of the shared bottom source/drain structure and the bottom spacer.

13. The semiconductor device of claim 8, further comprising:
a first electrical contact on a top surface of the first top source/drain structure;
a second electrical contact on a top surface of the second top source/drain structure; and
a third electrical contact on a bottom surface of the conductor part of the shared bottom source/drain structure.

14. The semiconductor device of claim 8, wherein the first top source/drain structure and the second top source/drain structure each include a respective doped semiconductor part and a conductor part.

15. A method of forming a semiconductor device, comprising:
forming a first semiconductor fin on a substrate;
forming a bottom source/drain structure under the first semiconductor fin;
forming a top source/drain structure over the first semiconductor fin;
removing the substrate; and
metallizing a bottom surface of the bottom source/drain structure.

16. The method of claim 15, further comprising etching a recess in the bottom surface of the bottom source/drain structure before metallizing the bottom surface of the bottom source/drain structure.

17. The method of claim 15, further comprising forming a dielectric liner at sidewalls of the bottom source/drain structure.

18. The method of claim 17, further comprising recessing the dielectric liner before metallizing the bottom surface of the bottom source/drain structure so that the sidewalls of the bottom source/drain structure are also metallized.

19. The method of claim 17, further comprising:
forming a second semiconductor fin on the substrate, wherein forming the bottom source/drain structure also forms the bottom source/drain structure under the second semiconductor fin.

20. The method of claim 15, further comprising metallizing a top surface of the top source/drain structure.
